(19) United States
(12) Patent Application Publication
(10) Pub. No.: US 2008/0174971 A1
(43) Pub. Date: Jul. 24, 2008

(54) Latch mechanism of notebook computer

(75) Inventors: Ming-Cheng Liu, Taipei Shien (TW); Tung-Yang Hu, Taoyuan Shien (TW)

Correspondence Address: RABIN & Berdo, PC, 1101 14TH STREET, NW, SUITE 500, WASHINGTON, DC, 20005, US

(73) Assignee: Quanta Computer Inc., Tao Yuan Shien (TW)

(21) Appl. No.: 11/727,826

(22) Filed: Mar. 28, 2007

(30) Foreign Application Priority Data
Jan. 19, 2007 (TW) 096201172

(51) Int. Cl. H05K 5/03

(52) U.S. Cl. 361/732

(57) ABSTRACT

A latch mechanism for fastening a display portion of a notebook computer to a main body thereof is described. A latch member is pivotally connected within the main body of the notebook computer. A magnet member is disposed within the display portion of the notebook computer. When the display portion is laid against the main body, the latch member, which is attracted by the magnet member, swivels out of the main body and engages with a latch hole on the display portion. A first movable bar, a second movable bar and a button are disposed in the display portion. When the button is pressed, the button pushes the first movable bar along a first direction; the first movable bar pushes the second movable bar along a second direction so as to remove the latch member out of the latch hole. The first direction is perpendicular to the second direction.

### RELATED APPLICATIONS

The present application claims priority to Taiwan Application Serial Number 96201172, filed Jan. 19, 2007, which is herein incorporated by reference.

### BACKGROUND

1. Field of Invention

The present invention relates to a latch mechanism for fastening a display portion of a notebook computer to a main body of the notebook computer.

2. Description of Related Art

A conventional notebook computer usually consists of a main body (with a keyboard) and a display portion (with a LCD panel). The display portion is pivotally connected with the main body by a hinge such that the display portion is capable of being swiveled relative to the main body and being laid against the main body. When the display portion is laid against the main body, a latch mechanism is necessary to lock or unlock the display portion to the main body.

Although the latch mechanism of a notebook computer already has various designs, efforts are still needed to improve the latch mechanism so as to create a more convenient way to operate the notebook computer.

### SUMMARY

A latch mechanism for fastening a display portion of a notebook computer to a main body thereof is described. The display portion is pivotally connected with the main body such that the display portion is capable of being swiveled relative to the main main body such that the display portion is capable of being swiveled relative to the main body and being laid against the main body. A latch member is pivotally connected within the main body of the notebook computer. A magnet member is disposed within the display portion of the notebook computer. When the display portion is laid against the main body, the latch member, which is attracted by the magnet member, swivels out of the main body and engages with a latch hole on the display portion. A first movable bar, a second movable bar and a button are disposed in the display portion. When the button is pressed, the first movable bar is pushed by the button along a first direction, the second movable bar is pushed by the first movable bar along a second direction so as to remove the latch member out of the latch hole. The first direction is perpendicular to the second direction.

It is to be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 illustrates a notebook computer according to one embodiment of this invention;

FIG. 2 illustrates a latch mechanism of a notebook computer according to one embodiment of this invention; and

FIG. 3 and FIG. 4 illustrate how a latch mechanism operates according to one embodiment of this invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

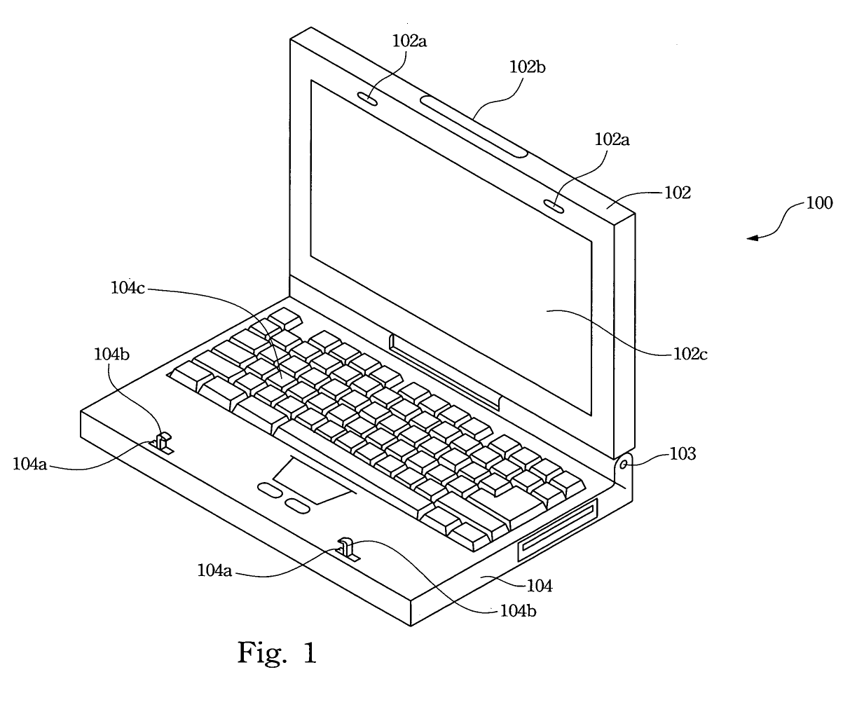

FIG. 1 illustrates a notebook computer according to one embodiment of this invention. The notebook computer 100 includes a main body 104 and a display portion 102. The display portion 102 is pivotally connected with the main body 104 by a hinge 103. Thus, the display portion 102 can be swiveled (relative to the main body 104) to a desired position and be laid against the main body 104, i.e. a surface having an LCD panel 102c (of the display portion 102) is laid against a surface having a keyboard 104c (of the main body 104). When the display portion 102 is laid against the main body 104, a latch member 104b (installed within a latch residence cavity 104a) come out of the main body 104 and engages with a latch hole 102a of the display portion 102 so as to fasten the display portion 102 to the main body 104. When a button 102b of the display portion 102 is pressed (by a user), the latch member 104b is removed from the latch hole 102a and the display portion 102 can be swiveled relative to the main body 104 at will.

A latch mechanism of the notebook 100 is responsible for swiveling the latch member 104b out of the main body 104, engaging the latch member 104b with the latch hole 102a, and removing the latch member 104b form the latch hole 102a. The latch mechanism is described below.

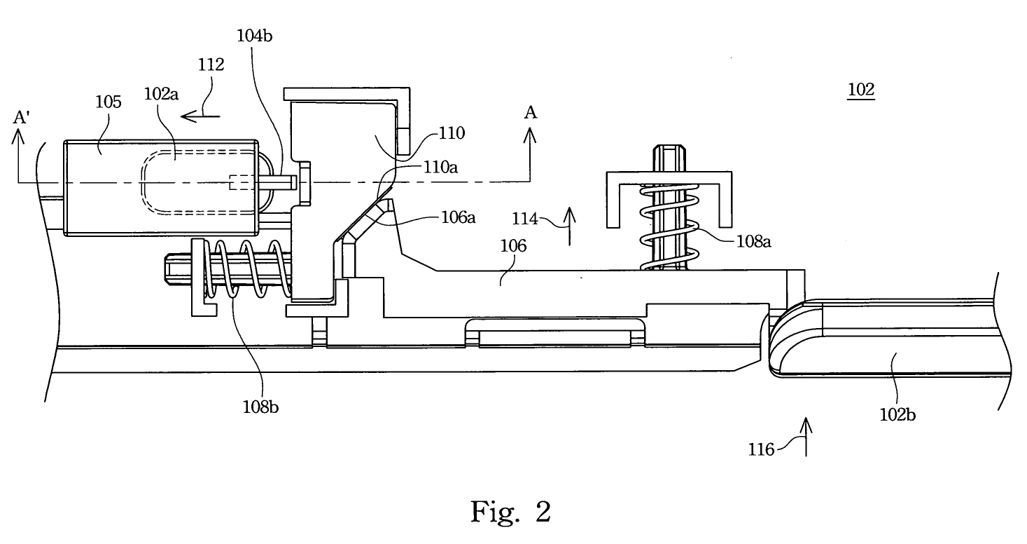

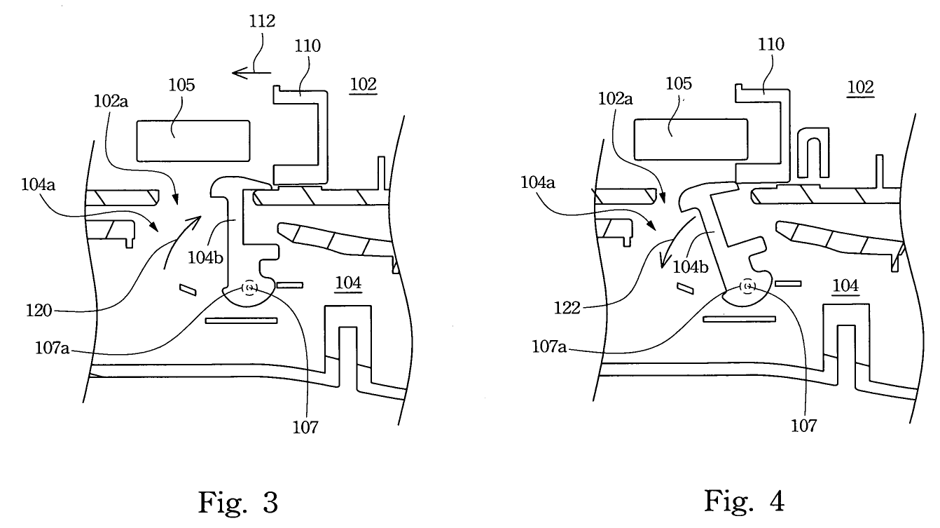

Please refer to FIGS. 2-4. FIG. 2 illustrates the display portion 102 with its top casing removed when the display portion 102 is laid against the main body 104. FIG. 3 and FIG. 4 illustrate cross-sectional views taken along the line A-A′.

The latch member 104b is pivotally connected within the main body 104 by an axis 107. When the display portion 102 is laid against the main body 104, the latch member 104b, which is attracted by a magnet member 105 of the display portion 102, swivels out of the latch residence cavity 104a (the main body 104) along a direction 120 and engages with the latch hole 102a of the display portion 102 (as illustrated in FIG. 3).

Please refer to FIG. 2 and FIG. 4. How the latch mechanism removes the latch member 104b form the latch hole 102a is described. When the button 102b is pressed along a direction 116, a movable bar 106 is pushed along a direction 114 and a compression coil spring 108a is compressed. In contrast, the movable bar 106 is pushed along a direction inverse the direction 114 by the compressed compression coil spring 108a when the button 102b is no longer pressed.

When the movable bar 106 is pushed along the direction 114, a contact surface 106a of the movable bar 106 slides on a contact surface 110a of a movable bar 110 (namely, the movable bar 106 is slidingly connected with the movable bar 110), the movable bar 110 is thus pushed along a direction 112 and a compression coil spring 108b is compressed. The direction 112 is perpendicular to the direction 114. In contrast, the movable bar 110 is pushed along a direction inverse the direction 112 by the compressed compression coil spring 108b when the movable bar 110 is no loner pushed by the movable bar 106 (namely, the button 102b is no longer pressed). The compression coil springs 108a and 108b are designed to resist being compressed.

When the movable bar 110 moves along the direction 112 (as illustrated in FIG. 4), the latch member 104b is removed from the latch hole 102a (pushed by the movable bar 110) and the display portion 102 is no longer fastened to the main body 104. When the latch member 104b is removed from the latch hole 102a, a torsion spring 107a, which is disposed around the axis 107, further swivels back the latch member 104b to the latch residence cavity 104a (of the main body 104) along a direction 122.

According to embodiments discussed above, the latch mechanism of the present invention utilize a magnet to actuate a latch member so as to fasten a display portion of a notebook computer to a main body thereof, and unlock the latch member by pushing a button of the display portion.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A latch mechanism for fastening a display portion of a notebook computer to a main body thereof, wherein the display portion is pivotally connected with the main body such that the display portion is capable of being swiveled relative to the main body and being laid against the main body, the latch mechanism comprising:
a latch member, pivotally connected within the main body of the notebook computer;
a magnet member, disposed within the display portion of the notebook computer,
when the display portion is laid against the main body, the latch member, which is attracted by the magnet member, swivels out of the main body and engages with a latch hole on the display portion; and
a first movable bar, a second movable bar and a button, being interconnected in the display portion,
when the button is pressed, the first movable bar is pushed by the button along a first direction, the second movable bar is pushed by the first movable bar along a second direction so as to remove the latch member out of the latch hole, wherein the first direction is perpendicular to the second direction.

2. The latch mechanism of claim 1, wherein the first movable bar is slidingly connected with the second movable bar.

3. The latch mechanism of claim 2, wherein the first movable bar is slidingly in contacted with the second movable bar.

4. The latch mechanism of claim 2, further comprising a torsion spring disposed around an axis with which the latch member is pivotally connected, when the display portion is not laid against the main body, the torsion spring swivels back the latch member to the main body.

5. The latch mechanism of claim 2, further comprising a compression coil spring disposed within the display portion, when the button is not pressed, the compression coil spring pushes back the first movable bar along a direction inverse to the first direction.

6. The latch mechanism of claim 2, further comprising a compression coil spring disposed within the display portion, when the button is not pressed, the compression coil spring pushes back the second movable bar along a direction inverse to the second direction.

7. The latch mechanism of claim 1, wherein the first movable bar is slidingly in contacted with the second movable bar.

8. The latch mechanism of claim 1, further comprising a torsion spring disposed around an axis with which the latch member is pivotally connected, when the display portion is not laid against the main body, the torsion spring swivels back the latch member to the main body.

9. The latch mechanism of claim 1, further comprising a compression coil spring disposed within the display portion, when the button is not pressed, the compression coil spring pushes back the first movable bar along a direction inverse to the first direction.

10. The latch mechanism of claim 1, further comprising a compression coil spring disposed within the display portion, when the button is not pressed, the compression coil spring pushes back the second movable bar along a direction inverse to the second direction.
